(19) United States
(12) Patent Application Publication
(10) Pub. No.: US 2013/0098754 A1
(43) Pub. Date: Apr. 25, 2013

(54) TRANSPARENT CONDUCTIVE COMPOSITION, TARGET, TRANSPARENT CONDUCTIVE THIN FILM USING THE TARGET AND METHOD FOR FABRICATING THE SAME

(71) Applicant: Korea Institute of Science and Technology, Seoul (KR)

(72) Inventors: Ji Won CHOI, Seoul (KR); Seok Jin YOON, Seoul (KR); Won Kook CHOI, Seoul (KR); Jin Sang KIM, Seoul (KR); Chong Yun KANG, Seoul (KR); Ho Won JANG, Daegu (KR); Keun JUNG, Gyeonggi-do (KR)

(73) Assignee: KOREA INSTITUTE OF SCIENCE AND TECHNOLOGY, Seoul (KR)

(21) Appl. No.: 13/692,821

(22) Filed: Dec. 3, 2012

(30) Foreign Application Priority Data
Feb. 22, 2011 (KR) 10-2011-0015507

(51) Int. Cl. C23C 14/08

(52) U.S. Cl. CPC C23C 14/086
USPC 204/192.29

(57) ABSTRACT

Disclosed are a transparent conductive composition including a material of the following formula, a target, a transparent conductive thin film using the target, and a method for fabricating the same. The disclosed transparent conductive composition and transparent conductive thin film have superior conductivity (low resistivity) and high light transmittance. Especially, they may be usefully applied for the flexible electronic devices, which may be called the core of the future display industry, because they have low resistivity of not greater than 10⁻³ Ω·cm and a high light transmittance of at least 90% even when deposition is carried out at room temperature.

AlₓZn₁₋ₓO

In the above formula, x is within the range of 0.04≦x≦0.063.

### CROSS-REFERENCE TO RELATED APPLICATION

This application claims priority to Korean Patent Application No. 10-2011-0015507, filed on Feb. 22, 2011, and all the benefits accruing therefrom under 35 U.S.C. §119, the contents of which in its entirety are herein incorporated by reference.

### BACKGROUND

1. Field

The present disclosure relates to a transparent conductive composition, a target, a transparent conductive thin film using the target, and a method for fabricating the same. More particularly, the present disclosure relates to a transparent conductive composition having zinc oxide (ZnO) doped with a trivalent metal element at a specific ratio and thus having excellent conductivity (low resistivity) and light transmittance, a target, a transparent conductive thin film using the target, and a method for fabricating the same.

2. Description of the Related Art

Recently, transparent conductive thin films are actively studied. The transparent conductive thin film is practically utilized for flat panel displays, light emitting diodes, solar cells, etc., and its application is gradually expanding.

The transparent conductive thin film requires superior conductivity and light transmittance in the visible and near infrared regions. Especially, for the flexible electronic devices, which may be called the core of the future display industry, fabrication of the transparent conductive thin film at room temperature or low temperature is very important. Since the flexible electronic device employs a plastic substrate, it is deformed easily at elevated temperatures. Thus, for application of the transparent conductive thin film to the flexible electronic devices, it is required that superior conductivity and light transmittance be achieved even when it is fabricated at room temperature.

At present, indium tin oxide (ITO) thin film, obtained by doping indium oxide with an adequate amount of tin, is the most frequently used transparent conductive thin film. The biggest reason why the ITO thin film is the most frequently used as the transparent conductor is because it has lower resistivity as compared to thin films made from other materials and exhibits high light transmittance in the visible region. However, the ITO thin film is disadvantageous in that the source material indium (In) is expensive and rare, causing cost increase and supply shortage problems. Furthermore, the ITO thin film is not easily patterned by wet etching using an acid solution in the semiconductor process and, when fabricated at low temperature, fails to maintain a low specific resistance, which makes it inapplicable to the flexible electronic devices.

To solve this problem, zinc oxide (ZnO)-based transparent conductive thin films wherein ZnO is doped with a dopant have been recently developed. The conductivity of ZnO may be changed due to internal defects caused by oxygen vacancy or zinc penetration or substitution by external dopants. Candidate dopants having a valence of 3 or 4, such as Al, Ga and Sn, have been explored.

However, the resistivity is very high when compared to the ITO thin film. In most of existing methods, a metal oxide of a metal having a larger valence than that of zinc, i.e. 2, such as Al, is added to ZnO within adequate concentration ranges to prepare a target, a film is formed on a substrate by sputtering the target, and then a resistivity is evaluated. However, since the existing method is capable of addition of only a discretized, limited amount of the dopant, the resulting film has a much higher resistivity than that of the ITO thin film. In particular, one deposited at room temperature exhibits a high resistivity (low conductivity) of 10⁻² to 10⁻³ Ω·cm.

### SUMMARY

The present disclosure is directed to providing a transparent conductive composition having superior conductivity (low resistivity) and light transmittance, fabricated by doping zinc oxide (ZnO) with a trivalent metal element at a specific ratio not known previously, a target for fabricating a thin film, a transparent conductive thin film fabricated from the target, and a method for fabricating the transparent conductive thin film.

In one aspect, there are provided a transparent conductive composition including a material of the following formula and a target for fabricating a transparent conductive thin film:

AlₓZn₁₋ₓO

wherein x is within the range of 0.04≦x≦0.063.

In another aspect, there is provided a transparent conductive thin film including the material of the above formula and having a specific resistance of not greater than 10⁻³ Ω·cm and a light transmittance of at least 90%.

In another aspect, there is provided a method for fabricating a transparent conductive thin film including: preparing the target including the material of the above formula; and depositing the target on a substrate by sputtering it at room temperature.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 shows electrical property (resistivity) of an aluminum (Al)-doped zinc oxide (AZO) target fabricated according to an embodiment of the present disclosure as a function of the distance from the substrate; and

FIG. 2 shows electrical property (resistivity) of an AZO thin film fabricated according to an embodiment of the present disclosure as a function of the thin film composition.

### DETAILED DESCRIPTION

Exemplary embodiments now will be described more fully hereinafter with reference to the accompanying drawings, in which exemplary embodiments are shown. The present disclosure may, however, be embodied in many different forms and should not be construed as limited to the exemplary embodiments set forth therein. Rather, these exemplary embodiments are provided so that the present disclosure will be thorough and complete, and will fully convey the scope of the present disclosure to those skilled in the art. In the description, details of well-known features and techniques may be omitted to avoid unnecessarily obscuring the presented embodiments.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The inventors of the present disclosure have performed researches on the composition of a zinc oxide (ZnO)-based transparent conductive thin film. Through investigation based on the continuous composition spread technique, they have found out that superior electrical and optical properties can be attained with a previously unknown specific composition. As used herein, the term “continuous composition spread technique” refers to a method allowing exploration of chemical composition providing superior properties in short time by depositing thin films with continuously different compositions on a substrate. The inventors have explored the composition giving excellent properties by employing the continuous composition spread technique.

Specifically, the inventors have explored the composition giving superior properties by sputtering ZnO and an oxide of a trivalent metal element onto a single substrate continuously and simultaneously using independent guns facing the substrate perpendicularly and have evaluated the properties of the deposited oxide as a function of the substrate position. As a result, they have found out that superior electrical and optical properties can be achieved even when deposition is performed at room temperature if ZnO is doped (substituted) with aluminum (Al) as the trivalent metal element at a specific ratio.

Accordingly, the present disclosure provides an Al³⁺-doped ZnO-based transparent conductive composition and a target for a thin film comprising a material of the following formula. The transparent conductive thin film comprises the material of the following formula, and has a specific resistance of not greater than 10⁻³ Ω·cm and a light transmittance of at least 90%.

AlₓZn₁₋ₓO

In the above formula, the atomic fraction x satisfies the relationship: 0.04≦x≦0.063. When the fraction x is outside the above range, it is difficult to achieve the desired superior conductivity (low resistivity) and high light transmittance of 90% or more. When the fraction x is smaller than 0.04, resistivity may increase and, at the same time, light transmittance may decrease. And, when the fraction x exceeds, 0.063 resistivity may increase. Specifically, the fraction x may satisfy the relationship: 0.042≦x≦0.055. More specifically, the fraction x may satisfy the relationship: 0.045≦x≦0.052. In that case, better electrical and optical properties may be achieved.

As described above, the fraction was found by the continuous composition spread technique. Specifically, ZnO and aluminum oxide (Al₂O₃) were continuously deposited on a substrate by off-axis RF sputtering using sputter guns loaded with each oxide at an angle of 90° to the substrate, with varying compositions at differing position of the substrate. Evaluation of the electrical and optical properties upon the deposition at differing position revealed that excellent result is obtained when the (atomic) fraction of Al satisfies the relationship: 0.04≦x≦0.063. That is to say, superior electrical and optical properties were achieved when Al₂O₃ was included in the range of 2.6 (wt %)≦Al₂O₃≦4.19 (wt %), based on weight.

Also, using the oxide deposited by off-axis RF sputtering as a target, an Al-doped ZnO-based transparent conductive thin film (AZO thin film) having a low specific resistance of not greater than 10⁻³ Ω·cm and a high light transmittance of at least 90% could be fabricated through deposition at room temperature through on-axis RF sputtering under appropriate gas pressure conditions, using a sputter gun arranged at an angle of 180°. Among the prepared AZO thin films, some thin film of particular composition showed a very low resistivity in the order of 10⁻⁴ Ω·cm, specifically 6.5×10⁻⁴ Ω·cm.

The present disclosure also provides a method for fabricating a transparent conductive thin film, comprising: a first step of preparing a target comprising the material of the above formula; and depositing the target on a substrate by sputtering it at room temperature.

As described, in the first step, ZnO and Al₂O₃ are continuously sputtered on a substrate using independent guns perpendicularly facing the substrate. As a result, the target (oxide) having the above chemical composition is obtained as Al³⁺ is continuously substituted (doped) at the Zn⁺² site. And, in the second step, the target (oxide) obtained in the first step is deposited at room temperature by on-axis RF sputtering using a sputter gun provided at an angle of 180° with the substrate. The deposition in the second step may be performed at a gas pressure of 1 to 50 mTorr, more specifically 1 to 10 mTorr.

As described above, the present disclosure provides superior conductivity (low resistivity) and light transmittance due to the previously unknown specific chemical composition. By replacing the indium tin oxide (ITO) thin film, the transparent conductive thin film (AZO thin film) according to the present disclosure may allow cost reduction and provide environmental protection. The AZO thin film according to the present disclosure may be used, for example, as transparent conductors (electrodes) of flat panel displays, light emitting diodes, solar cells, etc., or for electromagnetic shielding. Especially, it may be usefully applied for the flexible electronic devices, which may be called the core of the future display industry, because it has superior conductivity and light transmittance although the deposition is carried out at room temperature.

### EXAMPLES

The examples and experiments will now be described. The following examples and experiments are for illustrative purposes only and not intended to limit the scope of the present disclosure.

<Exploration of Composition and Preparation of Target>

First, a 6-inch glass substrate was mounted on a sputtering device. Then, oxides were deposited on the glass substrate by off-axis RF sputtering using sputter guns arranged at an angle of 90° with the substrate. Specifically, zinc oxide (ZnO) and aluminum oxide (Al₂O₃) were deposited on the 6-inch glass substrate by off-axis RF sputtering using sputter guns loaded with each oxide at an angle of 90° to the substrate. The ZnO gun and the Al₂O₃ gun were operated at a power of 150 W and 300 W, respectively. Gas pressure during the deposition was adjusted to 20 mTorr using pure argon (Ar). The deposition was performed at room temperature for 10 minutes. As a result, an Al-doped ZnO (AZO) target (Al-doped ZnO thin film) with oxides having different composition continuously deposited on the single glass substrate was obtained.

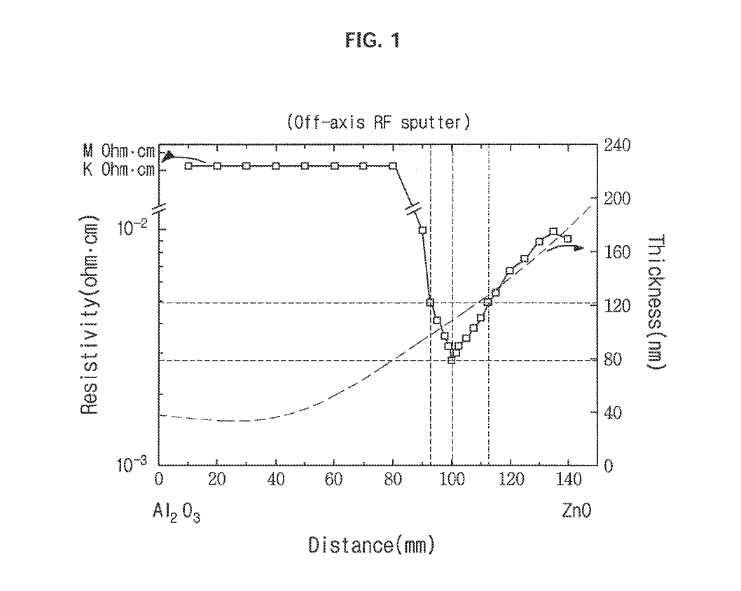

FIG. 1 shows electrical property (resistivity) of thus obtained AZO target as a function of the distance from the substrate. For evaluation of the electrical property of the deposited AZO target (oxide thin film), sheet resistance was measured using an automated probe station, thickness was measured by scanning electron microscopy (SEM), and then specific resistance (resistivity) was calculated.

As seen from FIG. 1, the AZO target showed varying electrical property depending on the composition. Specifically, overload characteristic were detected in the distance range from 0 to 80 mm, i.e. the Al₂O₃-rich region, and a specific resistance of 10⁻² Ω·cm was observed detected in the distance range from 80 to 150 mm, which is the ZnO-rich region. A superior property (specific resistance) was achieved in the distance range from 92 to 112 mm, which is appropriate composition of ZnO and Al₂O₃. Especially, a very low specific resistance of 2.8×10⁻³ Ω·cm was achieved when the distance was 100 mm.

To conclude, the composition giving superior electrical property could be explored conveniently by continuously depositing a thin film with different composition at differing substrate position by the continuous composition spread technique and evaluating the property of the deposited thin film. As a result, a superior property was achieved in the distance range from 92 to 112 mm, as seen in FIG. 1.

Table 1 shows an analysis result of composition and electrical and optical properties for the distance range from 92 to 112 mm.

TABLE 1
Electrical and optical properties depending on composition

| | Resistivity | Light trans- | Distance |
|---|---|---|---|
| Composition | (Ω · cm) | mittance (%) | (mm) |
| Al_{0.067}Zn_{0.933}O₁ | 9.1 × 10⁻³ | 96 | 90.0 |
| Al_{0.063}Zn_{0.937}O₁ | 4.9 × 10⁻³ | 96 | 92.5 |
| Al_{0.058}Zn_{0.942}O₁ | 4.1 × 10⁻³ | 96 | 95 |
| Al_{0.055}Zn_{0.945}O₁ | 3.5 × 10⁻³ | 96 | 97.5 |
| Al_{0.051}Zn_{0.949}O₁ | 3.2 × 10⁻³ | 95 | 98.7 |
| Al_{0.048}Zn_{0.952}O₁ | 2.8 × 10⁻³ | 95 | 100 |
| Al_{0.046}Zn_{0.954}O₁ | 3.0 × 10⁻³ | 95 | 101.2 |
| Al_{0.045}Zn_{0.955}O₁ | 3.2 × 10⁻³ | 94 | 102.5 |
| Al_{0.043}Zn_{0.957}O₁ | 3.4 × 10⁻³ | 94 | 105 |
| Al_{0.042}Zn_{0.958}O₁ | 3.8 × 10⁻³ | 94 | 107.5 |
| Al_{0.0403}Zn_{0.9597}O₁ | 4.2 × 10⁻³ | 93 | 110 |
| Al_{0.04}Zn_{0.96}O₁ | 4.9 × 10⁻³ | 93 | 112 |
| Al_{0.035}Zn_{0.965}O₁ | 6.3 × 10⁻³ | 89 | 120 |

As seen above, the composition giving superior electrical and optical property could be explored through the continuous composition spread technique. As seen from Table 1, superior electrical property (low resistivity) and optical property (high light transmittance) were achieved when the (atomic) fraction x of Al of the Al-doped ZnO AlₓZn₁₋ₓO satisfies the relationship: 0.04≦x≦0.063. Specifically, as seen from Table 1, a low resistivity not greater than 5.0×10⁻³ Ω·cm and a high light transmittance of at least 90% could be attained when 0.04≦x≦0.063. When x was smaller than 0.04, resistivity was high and light transmittance was unsatisfactory. And, when x exceeded 0.063, resistivity was high. When 0.042≦x≦0.055, resistivity was not greater than 3.5×10⁻³Ω·cm. When 0.045≦x≦0.052, resistivity was not greater than 3.2×10⁻³Ω·cm. Especially, resistivity was very low at 2.8×10⁻³ Ω·cm when x=0.048, an optimum composition.

<Fabrication of AZO Thin Film>

An AZO thin film was fabricated by using the AZO target (oxide thin film) prepared from the above exploration of composition at room temperature as follows.

The AZO target (oxide thin film) was deposited on a 1.5×1.5 cm-sized glass substrate by on-axis RF sputtering using sputter guns arranged with an angle of 180°. The sputtering was performed at room temperature for 60 minutes with a power of 60 W, using pure argon (Ar).

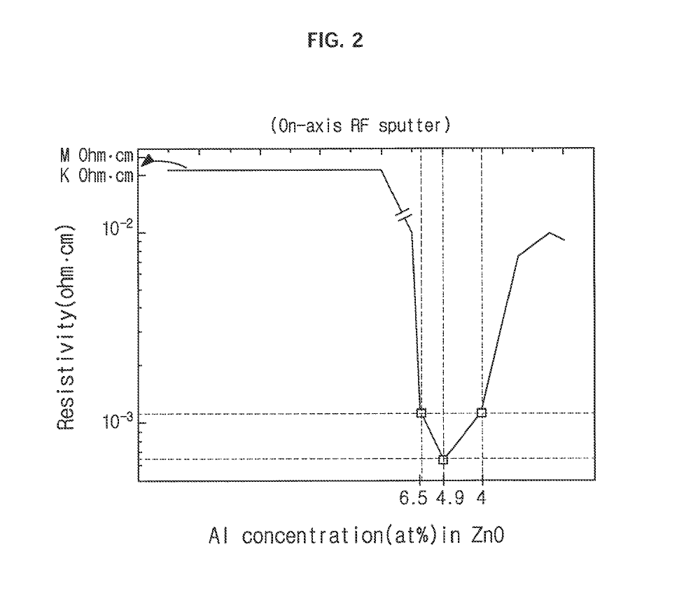

FIG. 2 shows electrical property (resistivity) of thus deposited AZO thin film as a function of the thin film composition. As seen from FIG. 2, when the fraction x of Al satisfied the relationship: 0.04≦x≦0.063, i.e. when the atomic fraction of Al was between 4 at % and 6.3 at %, superior resistivity of not greater than about 10⁻³ Ω·cm was achieved even though the deposition was carried out at room temperature. And, as seen in FIG. 2, resistivity increased sharply when the Al fraction x was smaller than 0.04 or larger than 0.063.

Table 2 shows an analysis result of electrical and optical properties of the AZO thin film fabricated by depositing the target that exhibited the best result in Table 1 (Al_{0.048}Zn_{0.952}O₁) at room temperature. Also given in Table 2 is the result of evaluating electrical property using the Hall measurement method. The AZO thin film was deposited at room temperature for 60 minutes, while varying the pressure of the pure Ar gas from 1 to 50 mTorr.

As seen from Table 2, although the deposition was performed by on-axis RF sputtering at room temperature, a low resistivity of not greater than 10⁻³ Ω·cm was achieved at appropriate gas pressure (1 mTorr and 5 mTorr). Especially, a very low resistivity of not greater than 6.5×10⁻⁴ Ω·cm was achieved at a pure Ar gas pressure of 5 mTorr. Also, average light transmittance of the fabricated AZO thin film in the visible region (400-700 nm) was high at 92% or above.

TABLE 2
Electrical property of AZO thin film depending on gas pressure

| | Gas pressure | Resistivity | Carrier concen- | Mobility |
|---|---|---|---|---|
| Composition | (pure Ar) | (Ω · cm) | tration (cm³) | (cm²/Vs) |
| Al_{0.048}Zn_{0.952}O₁ | 1 mTorr | 8.1 × 10⁻⁴ | 1.7 × 10²¹ | 6.3 |
| | 5 mTorr | 6.5 × 10⁻⁴ | 2.1 × 10²¹ | 4.9 |
| | 20 mTorr | 1.2 × 10⁻² | 2.8 × 10²⁰ | 1.0 |
| | 50 mTorr | 3.0 × 10⁻² | 2.5 × 10²⁰ | 0.5 |

As demonstrated by the foregoing examples, the oxide thin film composition giving the superior properties could be explored using the continuous composition spread technique. As a result, superior electrical and optical properties were attained when the Al fraction x satisfied the relationship: 0.04≦x≦0.063. Especially, when the gas pressure was maintained between 1 and 10 mTorr during the deposition at the optimum composition, a low resistivity in the order of 10⁻⁴ Ω·cm could be achieved even though the deposition was carried out at room temperature. More desirably, a very low resistivity of 6.5×10⁻⁴ Ω·cm could be achieved when the gas pressure was 5 mTorr.

The transparent conductive composition and the transparent conductive thin film according to the present disclosure, which comprise the material of the specific composition, have superior conductivity (low resistivity) and high light transmittance. Especially, they may be usefully applied for the flexible electronic devices, which may be called the core of the future display industry, because they have low resistivity of not greater than 10⁻³ Ω·cm and a high light transmittance of at least 90% even when deposition is carried out at room temperature.

While the exemplary embodiments have been shown and described, it will be understood by those skilled in the art that various changes in form and details may be made thereto without departing from the spirit and scope of the present disclosure as defined by the appended claims.

In addition, many modifications can be made to adapt a particular situation or material to the teachings of the present disclosure without departing from the essential scope thereof. Therefore, it is intended that the present disclosure not be limited to the particular exemplary embodiments disclosed as the best mode contemplated for carrying out the present disclosure, but that the present disclosure will include all embodiments falling within the scope of the appended claims.

1-6. (canceled)

7. A method for fabricating a transparent conductive thin film comprising:
preparing a target for fabricating a transparent conductive thin film comprising a material of the formula AlₓZn₁₋ₓO through exploration of a composition of the formula via evaluation of electrical and optical properties upon deposition at differing positions,
wherein the deposition deposits zinc oxide and aluminum oxide continuously on a substrate by off-axis RF sputtering using sputter guns, respectively loaded with zinc oxide and aluminum oxide, at an angle of 90° to the substrate with varying compositions at differing positions of the substrate, and
wherein x is within the range of 0.04≦x≦0.063; and
depositing the target on a substrate by sputtering it at room temperature.

8. The method for fabricating a transparent conductive thin film according to claim 7, wherein x is within the range of 0.042≦x≦0.055.

9. The method for fabricating a transparent conductive thin film according to claim 7, wherein the depositing the target on a substrate by sputtering it at room temperature is performed at a pressure of 1 to 10 mTorr.

10. The method for fabricating a transparent conductive thin film according to claim 8, wherein the depositing the target on a substrate by sputtering it at room temperature is performed at a pressure of 1 to 10 mTorr.
